(19) United States
(12) Patent Application Publication
(10) Pub. No.: US 2013/0309792 A1
(43) Pub. Date: Nov. 21, 2013

(54) LIGHT-EMITTING DIES INCORPORATING WAVELENGTH-CONVERSION MATERIALS AND RELATED METHODS

(71) Applicants: Michael A. Tischler, Vancouver (CA); Philippe M. Schick, Vancouver (CA)

(72) Inventors: Michael A. Tischler, Vancouver (CA); Philippe M. Schick, Vancouver (CA)

(21) Appl. No.: 13/770,435

(22) Filed: Feb. 19, 2013

Related U.S. Application Data
(60) Provisional application No. 61/649,465, filed on May 21, 2012.

(51) Int. Cl. H01L 33/50

(52) U.S. Cl. CPC H01L 33/50; H01L 22/14
USPC 438/28; 438/17

(57) ABSTRACT

In accordance with certain embodiments, light-emitting dies are fabricated on a substrate, separated from at least a portion of the substrate, and coated with a wavelength-conversion material.

### RELATED APPLICATION

This application claims the benefit of and priority to U.S. Provisional Patent Application No. 61/649,465, filed May 21, 2012, the entire disclosure of which is hereby incorporated herein by reference.

### FIELD OF THE INVENTION

In various embodiments, the present invention generally relates to light sources, and more specifically to phosphor-converted light sources.

### BACKGROUND

Electronic and optical devices are generally composed of crystalline layers formed on a substrate. In the case of optical devices such as light emitters, light detectors, solar cells, etc., it is often advantageous that the substrate be transparent in order to permit entry of light to or exit of light from the active device region, i.e., the active layers above the substrate that, e.g., emit or detect light. In some cases transparent substrates may be available, for example sapphire for the growth of GaN-based materials for visible or ultraviolet (UV) light emission or detection. In other cases, the substrate may not be transparent, for example silicon as a substrate for growth of GaN-based materials or GaAs as a substrate for growth of InAlGaP materials. The growth of GaN on silicon is of interest because of the widespread availability of very large, very high quality, low-cost silicon substrates. Such substrates would permit the low-cost fabrication of many devices simultaneously. However, for many applications the non-transparent substrate must be at least partially removed after growth of the device in order to permit entry of light into and/or exit of light from the device.

Substrate removal may also be used even when the substrate is transparent, or when transparency of the substrate is not required. In one example, substrate removal may enable very small die sizes (e.g., edge lengths, thicknesses, or odd shapes), where a large substrate thickness may complicate processing. Substrate removal may also be desired where the substrate or portions of the substrate may interfere with device operation. For example, substrate removal has been used to make flip-chip light emitters that essentially emit light from a flat plane. This may result in improved optical characteristics and facilitate integration into illumination devices. Substrate removal may also be desirable to reduce series resistance in devices where current flows through the substrate.

Substrate removal is often challenging because of the need to selectively remove the substrate without removing or damaging the overlying device structure. Furthermore, the resulting device structure is very thin, on the order of about 1 μm to about 20 μm, and thus difficult to handle. Substrate-removed dies typically have a lower yield and thus a higher cost. Furthermore, substrate removal becomes even more challenging when it is desired to integrate the light emitter with a light-conversion material, for example to make a phosphor-converted light-emitting diode (LED). An example of this is a GaN-based LED emitting in the 420-520 nm range coupled with a phosphor to create white light.

Therefore, in view of the foregoing, there is a need to produce light-emitting elements coupled with light-conversion materials after substrate removal in an economical and high-yield process.

### SUMMARY

Embodiments of the present invention enable the direct integration of a wavelength-conversion material (e.g., one or more phosphors) with a thin light-emitting element (LEE), e.g., an LED die having a thickness less than 50 μm, or less than 20 μm. Preferred embodiments of the invention feature batch processing of multiple LEEs on a starting substrate (which may be substantially opaque to the light emitted by the LEEs), mounting of the LEEs on a temporary substrate, removal of the starting substrate (either removal of the substrate from the LEEs or removal of the LEEs from the substrate), integration of the wavelength-conversion material, and release from the temporary substrate. The LEEs may be singulated at any of a variety of points in the process, e.g., before, during, or after removal of the starting substrate. As utilized herein, an LEE (e.g., an LED die) and a wavelength-conversion material are “integrated” when they are brought into contact and joined to become a unitary structure.

As utilized herein, the term “light-emitting element” (LEE) refers to any device that emits electromagnetic radiation within a wavelength regime of interest, for example, visible, infrared or ultraviolet regime, when activated, by applying a potential difference across the device or passing a current through the device. Examples of LEEs include solid-state, organic, polymer, phosphor-coated or high-flux LEDs, microLEDs (described below), laser diodes or other similar devices as would be readily understood. The emitted radiation of a LEE may be visible, such as red, blue or green, or invisible, such as infrared or ultraviolet. A LEE may produce radiation of a spread of wavelengths. A LEE may feature a phosphorescent or fluorescent material for converting a portion of its emissions from one set of wavelengths to another. A LEE may include multiple LEEs, each emitting essentially the same or different wavelengths. In some embodiments, a LEE is an LED that may feature a reflector over all or a portion of its surface upon which electrical contacts are positioned. The reflector may also be formed over all or a portion of the contacts themselves. In some embodiments, the contacts are themselves reflective.

A LEE may be of any size. In some embodiments, a LEEs has one lateral dimension less than 500 μm, while in other embodiments a LEE has one lateral dimension greater than 500 um. Exemplary sizes of a relatively small LEE may include about 175 μm by about 250 μm, about 250 μm by about 400 μm, about 250 μm by about 300 μm, or about 225 μm by about 175 μm. Exemplary sizes of a relatively large LEE may include about 1000 μm by about 1000 μm, about 500 μm by about 500 μm, about 250 μm by about 600 μm, or about 1500 μm by about 1500 μm. In some embodiments, a LEE includes or consists essentially of a small LED die, also referred to as a “microLED.” A microLED generally has one lateral dimension less than about 300 μm. In some embodiments, the LEE has one lateral dimension less than about 200 μm or even less than about 100 μm. For example, a microLED may have a size of about 225 μm by about 175 μm or about 150 μm by about 100 μm or about 150 μm by about 50 μm. In some embodiments, the surface area of the top surface of a microLED is less than 50,000 μm² or less than 10,000 μm². The size of the LEE is not a limitation of the present invention, and in other embodiments the LEE may be relatively larger, e.g., the LEE may have one lateral dimension on the order of at least about 1000 μm or at least about 3000 μm.

As used herein, “phosphor” refers to any material that shifts the wavelengths of light irradiating it and/or that is fluorescent and/or phosphorescent. As used herein, a “phosphor” may refer to only the powder or particles (of one or more different types) or to the powder or particles with the binder, and in some circumstances may refer to region(s) containing only the binder (for example, in a remote-phosphor configuration in which the phosphor is spaced away from the LEE). The terms “wavelength-conversion material” and “light-conversion material” are utilized interchangeably with “phosphor” herein. The light-conversion material is incorporated to shift one or more wavelengths of at least a portion of the light emitted by LEEs to other (i.e., different) desired wavelengths (which are then emitted from the larger device alone or color-mixed with another portion of the original light emitted by the LEE). A light-conversion material may include or consist essentially of phosphor powders, quantum dots, organic dyes, or the like within a transparent binder. Phosphors are typically available in the form of powders or particles, and in such case may be mixed in binders. An exemplary binder is silicone, i.e., polyorganosiloxane, which is most commonly polydimethylsiloxane (PDMS). Phosphors vary in composition, and may include lutetium aluminum garnet (LuAG or GAL), yttrium aluminum garnet (YAG) or other phosphors known in the art. GAL, LuAG, YAG and other materials may be doped with various materials including for example Ce, Eu, etc. The specific components and/or formulation of the phosphor and/or matrix material are not limitations of the present invention.

The binder may also be referred to as an encapsulant or a matrix material. In one embodiment, the binder includes or consists essentially of a transparent material, for example silicone-based materials or epoxy, having an index of refraction greater than 1.35. In one embodiment the binder and/or phosphor includes or consists essentially of other materials, for example fumed silica or alumina, to achieve other properties, for example to scatter light, or to reduce settling of the powder in the binder. An example of the binder material includes materials from the ASP series of silicone phenyls manufactured by Shin Etsu, or the Sylgard series manufactured by Dow Corning.

Herein, two components such as light-emitting elements and/or optical elements being “aligned” or “associated” with each other may refer to such components being mechanically and/or optically aligned. By “mechanically aligned” is meant coaxial or situated along a parallel axis. By “optically aligned” is meant that at least some light (or other electromagnetic signal) emitted by or passing through one component passes through and/or is emitted by the other.

Herein, a contact being “available for electrical connection” means the contact has sufficient free area to permit attachment to, e.g., a conductive trace, a circuit board, etc., and “free” means lacking any electrical connection (and in preferred embodiments, any mechanical connection) thereto.

In an aspect, embodiments of the invention feature a method of processing semiconductor devices. A plurality of semiconductor layers are formed on a substrate, at least some of the semiconductor layers collectively defining a light-emitting-diode (LED) structure. A plurality of conductive contacts are formed on the top surface of the semiconductor layers to define a plurality of LED dies disposed on the substrate. Each of the LED dies includes at least two of the conductive contacts on a first surface thereof. At least some of the LED dies are bonded to a temporary substrate, thereby forming a plurality of bonded LED dies each having at least two conductive contacts adjacent to the temporary substrate. (By “adjacent to” is meant that the contacts are disposed between the temporary substrate and the remaining portions of the LED dies, and/or that the contacts are disposed in contact with the temporary substrate or joined to the temporary substrate via another material such as an adhesive.) After the bonding, the bonded LED dies are removed from the substrate, the bonded LED dies remaining bonded to the temporary substrate. (Such “removal” means that the dies may be removed from the substrate or that the substrate may be removed from the dies.) A wavelength-conversion material is applied over the bonded LED dies, and the bonded LED dies are removed from the temporary substrate.

Embodiments of the invention feature one or more of the following in any of a variety of combinations. The plurality of LED dies may be at least partially separated at least in part by removing a portion of the substrate thereunder, each LED die remaining attached to (i) a portion of the substrate and/or (ii) another LED die via at least one tether (e.g., photoresist and/or a portion of at least one of the plurality of semiconductor layers). Removing the bonded LED dies from the substrate may include or consist essentially of breaking tethers. The substrate may be substantially opaque to a wavelength of light emitted by the LED dies. The substrate may include or consist essentially of silicon, GaAs, GaP, and/or sapphire. At least one of the semiconductor layers may include or consist essentially of silicon, GaAs, InAs, AlAs, InP, GaP, AlP, InSb, GaSb, AlSb, GaN, InN, AlN, SiC, ZnO, and/or an alloy or mixture thereof. Bonding at least some of the LED dies to the temporary substrate may include or consist essentially of bonding only some of the LED dies to the temporary substrate. The bonded LED dies may be singulated by removing, from between the bonded LED dies, (i) a portion of at least one of the plurality of semiconductor layers and/or (ii) a portion of the wavelength-conversion material. The bonded dies may be singulated after removing the bonded LED dies from the temporary substrate. Singulating the bonded LED dies may include or consist essentially of cutting, sawing, dicing, laser cutting, water jet cutting, or die cutting. The bonded dies may be singulated before removing the bonded LED dies from the temporary substrate. The bonded LED dies may be transferred from the temporary substrate to a second temporary substrate prior to singulation.

Removing the bonded LED dies from the substrate may include or consist essentially of removing at least a portion of the substrate by laser lift-off, wet chemical etching, dry etching, sand blasting, lapping, and/or polishing. Forming the plurality of semiconductor layers may include or consist essentially of epitaxial deposition. After forming the plurality of conductive contacts, a portion of at least one of the semiconductor layers may be removed, thereby at least partially separating the plurality of LED dies. A portion of the semiconductor substrate may also be removed. The substrate may include or consist essentially of a semiconductor substrate. The wavelength-conversion material may include or consist essentially of one or more phosphors, e.g., YAG:Ce, LuAG:Ce, aluminum garnet-based phosphor, nitride-based phosphor, oxynitride-based phosphor, silicate-based phosphor, and quantum dots. The wavelength-conversion material may include or consist essentially of a material selected from the group consisting of silicone, epoxy, glass, spin-on glass, polyimide, and polymers. The wavelength-conversion material may include or consist essentially of one or more phosphors and a silicone. The wavelength-conversion material may include or consist essentially of a material selected from the group consisting of fumed silica, fumed alumina, SiO₂, and Al₂O₃. The wavelength-conversion material may be applied over substantially all of each sidewall of each bonded LED die. Each sidewall may span between the first surface and a second surface opposite the first surface. Each bonded LED die may include electrical contacts only on the first surface thereof. Each bonded LED may emit substantially no light through the first surface thereof. Applying the wavelength-conversion material may include or consist essentially of dispensing, casting, molding, or compression molding. The wavelength-conversion material may include or consist essentially of an encapsulant, and the encapsulant may be cured. The thickness of the wavelength-conversion material on the bonded LED dies may be defined at least in part by the spacing between bonded LED dies on the temporary substrate. The bonded LED dies may be electrically tested. The temporary substrate may include or consist essentially of a material selected from the group consisting of UV release tape, UV release adhesive, thermal release tape, thermal release adhesive, silicone, water-soluble tape, and water-soluble adhesive.

In another aspect, embodiments of the invention feature a method of processing semiconductor devices. A plurality of semiconductor layers are epitaxially deposited on a semiconductor substrate, at least some of the semiconductor layers collectively defining a light-emitting-diode (LED) structure. A plurality of conductive contacts are formed on the top surface of the semiconductor layers. A portion of at least one of the semiconductor layers is removed, thereby at least partially separating a plurality of discrete LED dies disposed on the semiconductor substrate, each of the LED dies having at least two of the conductive contacts on a surface thereof. At least some of the LED dies are bonded to a temporary substrate, thereby forming a plurality of bonded LED dies. After bonding, the bonded LED dies are removed from the semiconductor substrate, the bonded LED dies remaining bonded to the temporary substrate. A wavelength-conversion material is applied over the bonded LED dies, and the bonded LED dies are removed from the temporary substrate.

In yet another aspect, embodiments of the invention feature an electronic device including or consisting essentially of a solid shaped volume of a polymeric binder, suspended within the binder, a light-emitting diode (LED) die having a first face, a second face opposite the first face, and at least one sidewall spanning the first and second faces, and disposed on the first face of the LED die, at least two spaced-apart contacts each having a free terminal end (i) not covered by the binder and (ii) available for electrical connection. The LED die has a thickness less than approximately 50 μm.

Embodiments of the invention feature one or more of the following in any of a variety of combinations. The thickness of the LED die may be less than approximately 20 μm, or even less than approximately 10 μm. The LED die may include or consist essentially of one or more active semiconductor layers not disposed on a semiconductor substrate. The LED die may include or consist essentially of a semiconductor material including or consisting essentially of GaAs, AlAs, InAs, GaP, AlP, InP, ZnO, CdSe, CdTe, ZnTe, GaN, AlN, InN, silicon, and/or an alloy or mixture thereof. The binder may include or consist essentially of silicone and/or epoxy. One or more additional LED dies may be suspended within the binder. Each of the additional LED dies may have a thickness less than approximately 50 μm, less than approximately 20 μm, or even less than approximately 10 μm. The binder may contain a wavelength-conversion material therein. The wavelength-conversion material may include or consist essentially of a phosphor and/or quantum dots. The binder may be transparent to a wavelength of light emitted by the LED die. The binder may contain a wavelength-conversion material for absorption of at least a portion of light emitted from the LED die and emission of converted light having a different wavelength, converted light and unconverted light emitted by the LED die combining to form substantially white light.

These and other objects, along with advantages and features of the invention, will become more apparent through reference to the following description, the accompanying drawings, and the claims. Furthermore, it is to be understood that the features of the various embodiments described herein are not mutually exclusive and can exist in various combinations and permutations. Reference throughout this specification to “one example,” “an example,” “one embodiment,” or “an embodiment” means that a particular feature, structure, or characteristic described in connection with the example is included in at least one example of the present technology. Thus, the occurrences of the phrases “in one example,” “in an example,” “one embodiment,” or “an embodiment” in various places throughout this specification are not necessarily all referring to the same example. Furthermore, the particular features, structures, routines, steps, or characteristics may be combined in any suitable manner in one or more examples of the technology. The term “light” broadly connotes any wavelength or wavelength band in the electromagnetic spectrum, including, without limitation, visible light, ultraviolet radiation, and infrared radiation. Similarly, photometric terms such as “illuminance,” “luminous flux,” and “luminous intensity” extend to and include their radiometric equivalents, such as “irradiance,” “radiant flux,” and “radiant intensity.” As used herein, the terms “substantially,” “approximately,” and “about” mean ±10%, and in some embodiments, ±5%. The term “consists essentially of” means excluding other materials that contribute to function, unless otherwise defined herein. Nonetheless, such other materials may be present, collectively or individually, in trace amounts.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1A is a cross-sectional schematic of unsingulated dies formed on a substrate in accordance with various embodiments of the invention;

FIG. 1B is a cross-sectional schematic of singulated dies formed on a substrate in accordance with various embodiments of the invention;

FIG. 1C a cross-sectional schematic of partially singulated dies formed on a substrate in accordance with various embodiments of the invention;

FIG. 2A is a cross-sectional schematic of singulated dies bonded to a temporary substrate in accordance with various embodiments of the invention;

FIG. 2B is a cross-sectional schematic of partially singulated dies bonded to a stamp in accordance with various embodiments of the invention;

FIG. 3A is a cross-sectional schematic of singulated dies transferred to the temporary substrate of FIG. 2A in accordance with various embodiments of the invention;

FIG. 3B is a cross-sectional schematic of singulated dies transferred to the stamp of FIG. 2B in accordance with various embodiments of the invention;

FIG. 4A is a cross-sectional schematic of the dies of FIG. 3A coated with a wavelength-conversion material in accordance with various embodiments of the invention;

FIG. 4B is a cross-sectional schematic of the dies of FIG. 3B coated with a wavelength-conversion material in accordance with various embodiments of the invention;

FIG. 5 is a cross-sectional schematic of a single die coated with a wavelength-conversion material in accordance with various embodiments of the invention;

FIG. 6A is a cross-sectional schematic of singulated dies bonded to a stamp in accordance with various embodiments of the invention;

FIG. 6B is a cross-sectional schematic of a freestanding group of dies coated with a wavelength-conversion material in accordance with various embodiments of the invention;

FIGS. 7A and 7B are cross-sectional schematics of a stamp that utilizes vacuum for bonding of dies thereto in accordance with various embodiments of the invention;

FIGS. 7C and 7D are cross-sectional schematics of the stamp of FIGS. 7A and 7B bonded to semiconductor dies in accordance with various embodiments of the invention; and

FIGS. 8A-8C are cross-sectional schematics of a stamp that utilizes fluid flow for bonding of dies thereto in accordance with various embodiments of the invention.

### DETAILED DESCRIPTION

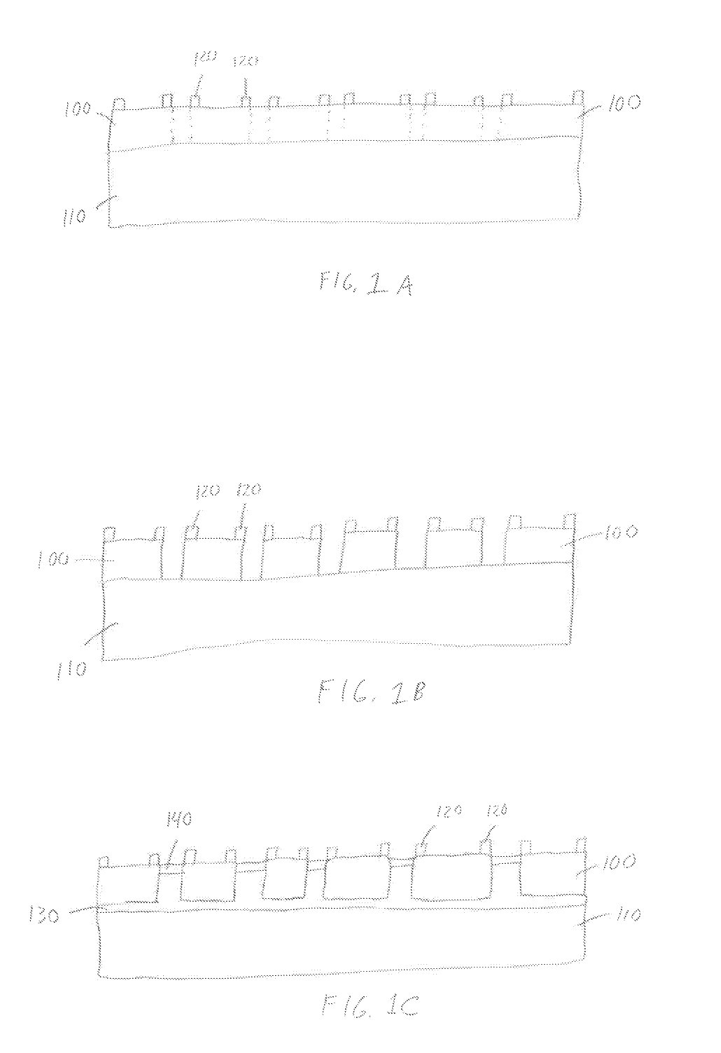

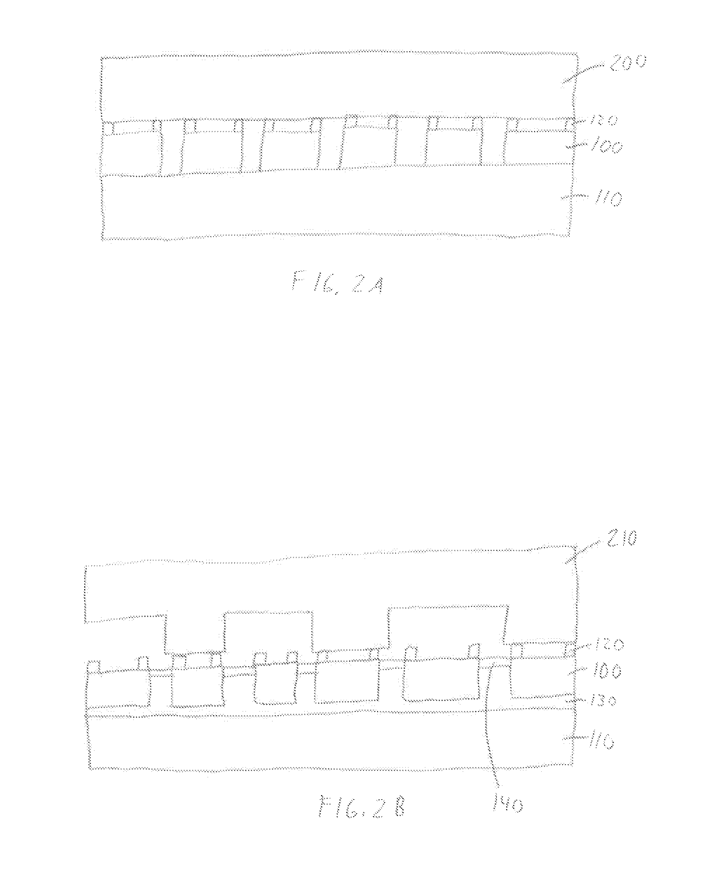

As shown in FIG. 1A, one or more LEE dies 100 are formed over a substrate 110. The dies 100 are formed by, e.g., epitaxial growth of multiple semiconductor layers over the substrate 110. The dies 100 may include or consist essentially of, e.g., III-nitride semiconductors such as GaN, AlGaN, InGaN, etc., and may thus emit, e.g., blue or UV light. In other embodiments, the dies 100 include or consist essentially of other semiconductor materials, for example GaAs, InAs, AlAs, GaSb, InSb, AlSb, GaP, AlP, InP, SiC, ZnO, and/or alloys of such compounds. The substrate 110 may be substantially transparent to the light emitted by the dies 100 (and may thus include or consist essentially of, e.g., sapphire, GaN, AN, or the like), but in preferred embodiments is substantially opaque to such light. For example, the substrate 110 may include or consist essentially of silicon, GaAs, InP, GaP, SiC, and the like. In some cases the substrate 110 may be transparent or opaque, depending on the concentration of one or more impurities. The thickness of the dies 100 may be, e.g., between approximately 1 μm and approximately 50 μm, while the thickness of the substrate 110 is typically substantially larger, e.g., between approximately 50 μm and approximately 3000 μm.

FIG. 1A depicts the LEE dies 100 prior to singulation (i.e., separation from each other for individual use and/or further processing), as embodiments of the invention feature singulation after the dies 100 are removed from the substrate 110. FIG. 1B depicts an array of singulated LEE dies 100, and the further processing steps described herein may be performed with either unsingulated or singulated dies 100 (or with partially singulated or “tethered and released” dies 100, as detailed below) unless otherwise indicated. At the stage depicted in FIG. 1B, the dies 100 may be singulated by, e.g., photolithographic masking and etching, sawing, laser cutting, or other techniques. In some embodiments of the invention, the dies 100 are only partially singulated at this stage, and a portion of the epitaxial material remains on substrate 110 between the dies 100. As shown in FIGS. 1A and 1B, the dies 100 typically have two contacts 120 (e.g., a p-contact and an n-contact) on a single surface, and thus may be considered “flip-chip” dies. In other embodiments of the invention, dies 100 have only one contact, or have more than two contacts. In some embodiments dies 100 further feature a reflecting surface or material over all or a portion of the surface on which the two contacts 120 are formed, resulting in substantially all of the light being emitted through the face opposite the contact face and the sides of dies 100.

As shown in FIG. 1C, in certain embodiments of the invention, the dies 100 are “pre-released” from substrate 110 in order to facilitate subsequent removal of substrate 110. As shown, the dies 100 have been undercut by, e.g., chemical etching, leaving dies 100 at least partially suspended over an air gap 130. For example, the epitaxial LEE structure on substrate 110 may include one or more bottom release layers that may be selectively etched away while layers thereabove are substantially unaffected, or a portion of substrate 110 may be removed from under dies 100 with or without the use of one or more additional release layers. The dies 100 may be interconnected and/or connected to substrate 110 (or to unreleased portions of epitaxial material thereon) each by one or more tethers 140. In some embodiments, the tethers 140 include or consist essentially of portions of the epitaxial material of which dies 100 are composed, and in other embodiments, the tethers 140 include or consist essentially of a different material, e.g., photoresist, metal, polyimide, or the like.

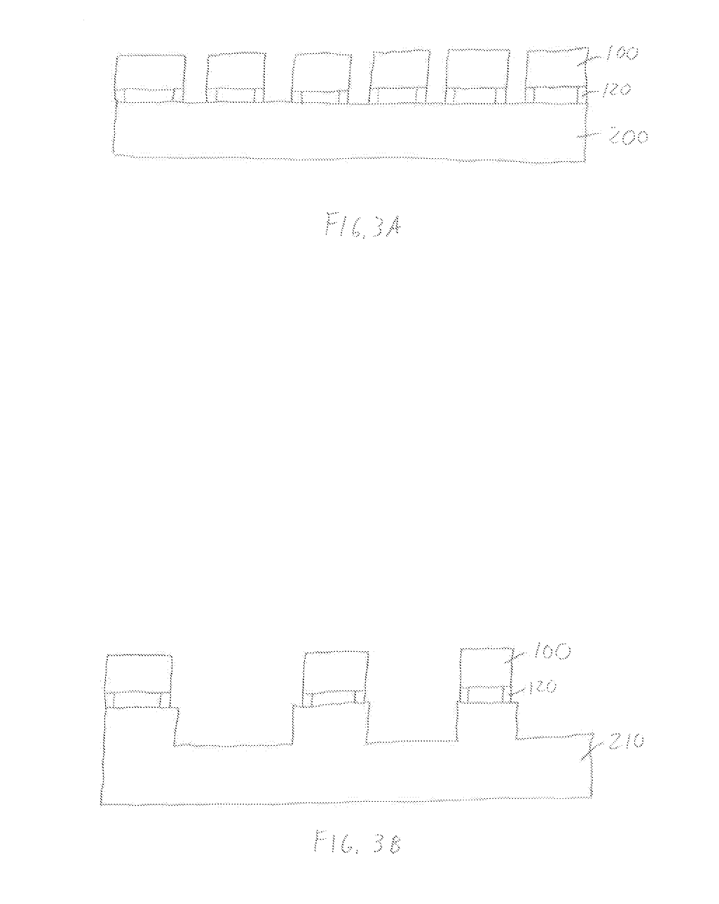

After the dies 100 (with contacts 120) are formed over substrate 110 and optionally partially or fully singulated, some or all of the dies 100 are temporarily bonded to a base 200 that provides mechanical support during subsequent removal of the substrate 110. As shown in FIG. 2A, the base 200 may be bonded at least to the contacts 120 of the dies 100; for example, the base 200 may be attached to the dies 100 via an adhesive material, sticky material (e.g., a silicone such as PDMS), or wax, or base 200 may include or consist essentially of such an adhesive material. In other embodiments, base 200 is bonded to all or a portion of contacts 120 and/or to a portion of dies 100. In some embodiments, all or a portion of contacts 120 are embedded in a portion of base 200. The base 200 may even incorporate through-holes, and vacuum may be utilized to temporarily attach the dies 100 to base 200. Base 200 may even include or consist essentially of an electrostatic chuck to temporarily attach the dies 100 to base 200. After bonding of base 200, the substrate 110 may be removed by, e.g., fracturing tethers of partially released dies, laser lift-off, wet chemical etching, dry etching, sand blasting, lapping, polishing, or a similar technique (or combination of such techniques), resulting in only the unsingulated or (partially or fully) singulated dies 100 bonded to base 200, as shown in FIG. 3A.

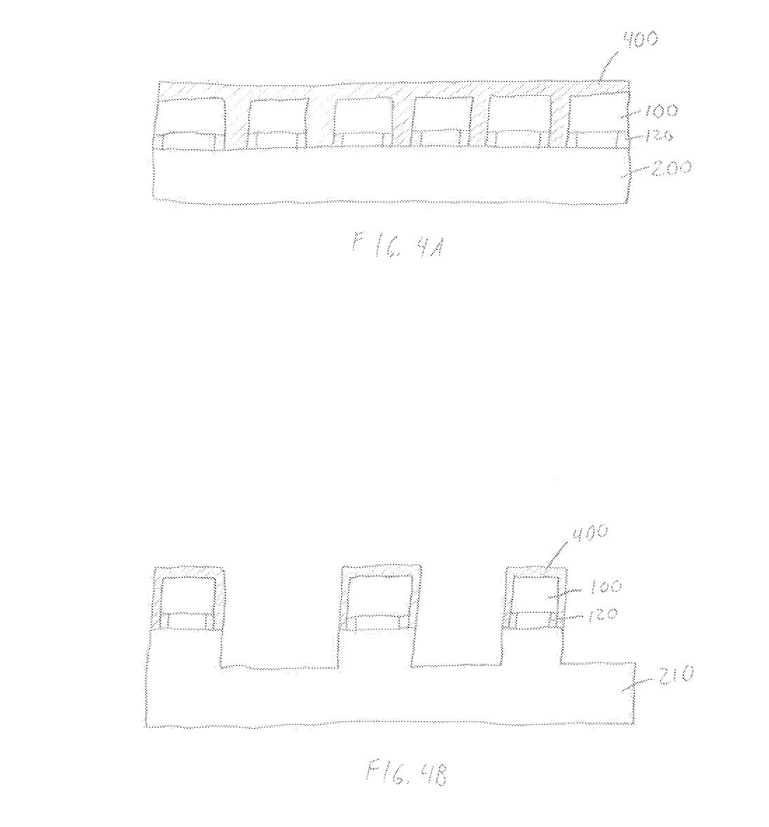

Similarly, one or more (or even all) of the dies 100 may be temporarily bonded to a stamp 210 similar to that utilized in conventional “pick-and-place” hybrid integration techniques or to adhesive-type stamps, for example ones including or consisting essentially of PDMS. As shown in FIG. 2B, the stamp 210 may feature protrusions for attaching to only some (e.g., every other one of) dies 100, thus permitting the removal of some of dies 100 from substrate 110. In other embodiments, stamp 210 does not feature protrusions, but still is able to remove a portion of dies 100 from substrate 110 (via, e.g., selective activation of particular regions thereof to bond to selected ones of the dies 100). As described above for base 200, the dies 100 are temporarily attached to the stamp 210 and then removed from substrate 110. Stamp 210 may utilize, e.g., an adhesive material, vacuum, and/or electrostatic force to temporarily bond the dies 100. If tethers 140 are present between the dies 100, then sufficient force is utilized to break the tethers 140 and free the dies 100 from other dies and/or the substrate 100, resulting in only the singulated dies 100 being temporarily bonded to stamp 210, as shown in FIG. 3B. The released dies 100 may remain temporarily bonded to the stamp 210 or may be transferred to another temporary substrate for further processing (much as illustrated in FIG. 3A and FIG. 4A).

After removal of the dies 100 from the substrate 110, a wavelength-conversion material 400 is applied to the dies while they remain temporarily bonded to base 200 or stamp 210, as shown in FIGS. 4A and 4B. Application or formation of the wavelength-conversion material 400 over dies 100 may be performed using a variety of techniques, e.g., dispensing, casting, molding, compression molding, or the like. In some embodiments, the wavelength conversion material 400 is cured or partially cured after formation over dies 100. Curing may be performed via a variety of techniques, for example, using heat, light, UV radiation, electron-beam radiation, or exposure to various chemical or vapor curing agents.

When the wavelength-conversion material 400 is applied, it may be applied over the entire assemblage of dies 100, as shown in FIG. 4A or may be applied individually to each die 100 as shown in FIG. 4B. For example, as detailed in U.S. patent application Ser. No. 13/748,864, filed Jan. 24, 2013, the entire disclosure of which is incorporated by reference herein, a phosphor-filled mold may be applied to the temporarily bonded dies 100, thereby providing the wavelength-conversion material 400 with a desired thickness and/or shape to each die 100. Because the base 200 or stamp 210 is bonded at least to the contacts 120 of the dies 100, the contacts 120 remain substantially free of the wavelength-conversion material 400 and thus electrically bondable (i.e., capable of direct electrical contact thereto) after removal from base 200 or stamp 210. That is, each of the contacts 120 preferably has a free terminal end that is not covered by the wavelength-conversion material 400 and that is available for electrical connection.

In some embodiments of the invention, base 200 includes or consists essentially of a material to which wavelength-conversion material 400 does not adhere well, permitting easy removal after molding. In some embodiments, base 200 includes or consists essentially of materials such as PDMS, UV release tape, UV release adhesive, thermal release tape, thermal release adhesive, silicone, water soluble tape, and water soluble adhesive. In some embodiments, the wavelength-conversion material 400 covers the top and the entirety of each sidewall of dies 100. In some embodiments the wavelength-conversion material 400 covers the top and only a portion of each sidewall of dies 100.

After application of the wavelength-conversion material 400, the dies 100 are singulated (if necessary) and removed from base 200 or stamp 210, resulting in coated dies 500 depicted in FIG. 5. In some embodiments, each die 100 has a thickness less than 50 μm, less than 20 μm, or even less than 10 μm. In some embodiments, die 100 consists essentially only of all or a portion of the layers formed over a semiconductor substrate (e.g., substrate 110), where the substrate has been removed prior to the stage shown in FIG. 5. In some embodiments, die 100 consists essentially only of all or a portion of the layers formed over a substrate and a portion of that substrate, where a portion of that substrate has been removed prior to the stage shown in FIG. 5. The coated dies 500 may be electrically and mechanically attached to a final substrate to form, e.g., an array of light emitters. For example, the coated dies 500 may be adhered and electrically connected to electrical traces by a conductive adhesive as described in U.S. patent application Ser. No. 13/171,973, filed Jun. 29, 2011, the entire disclosure of which is incorporated by reference herein.

Singulation may be accomplished by a variety of different techniques, including, for example, cutting, sawing, dicing, laser cutting, water jet cutting, die cutting, or the like. In some embodiments, singulation is performed while dies 100 are on base 200, as shown in the step depicted in FIG. 4A. In some embodiments, the structure comprising wavelength-conversion material 400 and dies 100 is transferred to another substrate for singulation. In some embodiments, the structure comprising wavelength-conversion material 400 and dies 100 is singulated in free-standing form (i.e., detached from base 200 or stamp 210). In some embodiments, dies 100 may be tested during this process. For example, a die 100 may be tested at the stages shown in FIGS. 1A, 1B, or 1C. In another embodiment, the structure comprising wavelength-conversion material 400 and dies 100 is transferred to another substrate such that contacts 120 are accessible, and testing is done at that stage, either before or after singulation.

In the example shown in FIG. 5, the wavelength-conversion material 400 has a thickness that is substantially the same over the sidewalls and top of die 100. However, this is not a limitation of the present invention, and in other embodiments wavelength-conversion material 400 is thicker on top than on the sidewalls, or thinner on the top than on the sidewalls. In some embodiments, wavelength-conversion material 400 has an arbitrary shape over dies 100, and may be formed during the molding process described above.

As may be seen by comparing FIG. 4A to FIG. 5, the thickness of wavelength-conversion material 400 on the sidewalls of dies 100 is in part controlled by the spacing between dies 100. In some embodiments, the thickness of wavelength-conversion material 400 on the sidewalls of dies 100 is about one-half the spacing between dies 100. In some embodiments, the thickness of wavelength-conversion material 400 on the sidewalls of dies 100 is about one-half of the spacing between dies 100 less about half a kerf, where the kerf is the thickness of material removed in the singulation process.

FIG. 5 shows coated die 500 including only one LEE die 100; however, this is not a limitation of the present invention, and in other embodiments a coated die 500 may include multiple LEE dies 100 coated with wavelength-conversion material 400.

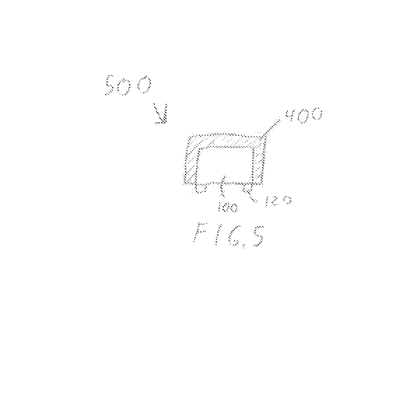

FIGS. 6A-6C depict another embodiment of the present invention related to that shown in FIGS. 2B, 3B and 4B. In this embodiment, stamp 210 is replaced by stamp 610 that is flat or substantially flat. FIG. 6A shows dies 100 after removal from substrate 110 being temporarily bonded to a flat stamp 610. At this point the process may proceed as described in reference to FIGS. 3A and 4A, utilizing flat stamp 610, resulting in the structure shown in FIG. 4A. The process may then continue as described with reference to FIG. 5. Alternately, stamp 610 may be removed, resulting in the structure shown in FIG. 6B. The dies 100 in FIG. 6B may then be tested in wafer form, where the “wafer” consists essentially of dies 100 and wavelength-conversion material 400. Singulation to form multiple coated dies 500 as shown in FIG. 5 may take place before or after testing.

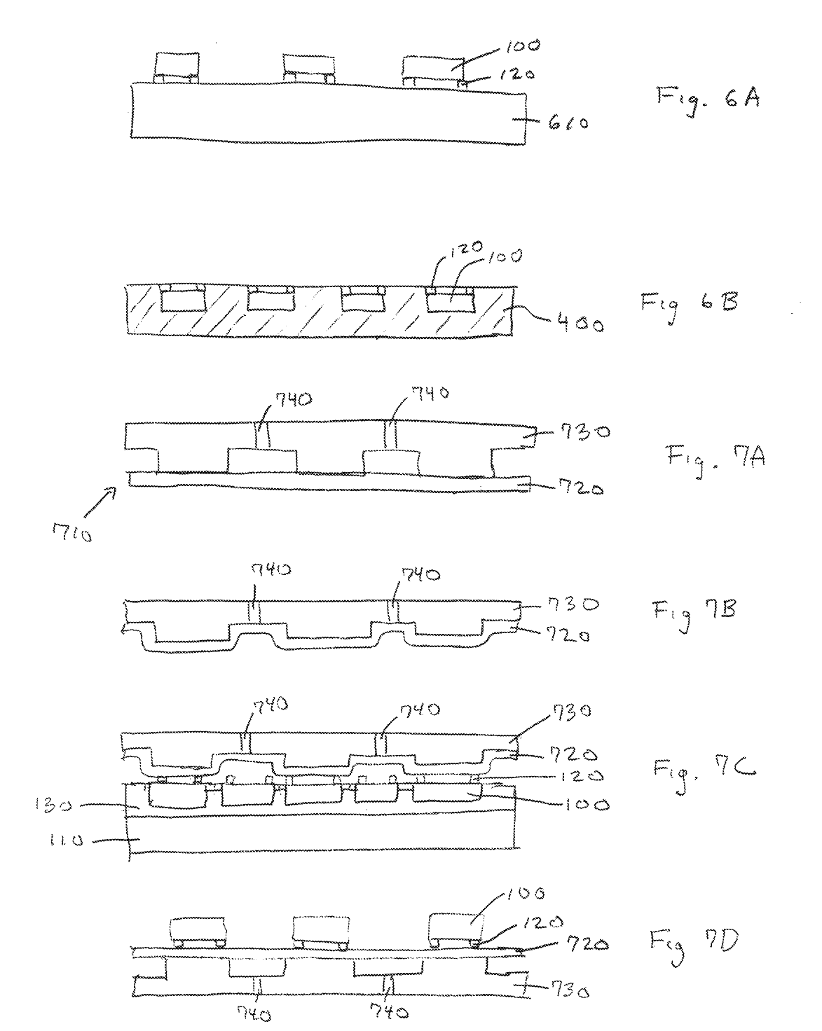

FIGS. 7A-7D depict another embodiment of the present invention related to that shown in FIGS. 2B, 3B and 4B. In this embodiment, stamp 210 is replaced by a stamp 710 that includes or consists essentially of a stamp material 720 and a support structure 730. Support structure 730 is a mechanism for applying vacuum to a portion of stamp material 720 such that portions of the surface of stamp material 720 may be recessed or made non-coplanar with other portions of the surface of stamp material 720. FIG. 7A depicts the stamp 710 with no vacuum applied to vacuum holes 740, while FIG. 7B shows stamp 710 with vacuum applied to vacuum holes 740. This permits temporary formation of a stamp structure similar to stamp structure 210 shown in FIG. 2B to pick up some of dies 100, as shown in FIG. 7C. After picking up some of the dies 100, the vacuum is removed, resulting in the structure shown in FIG. 7D, which is similar to that shown in FIG. 6A. In some embodiments, positive pressure may also be applied to vacuum holes 740. The process may then continue in various ways, as described above. In another embodiment, the structure shown in FIG. 7A is activated using fluidics or hydraulics. In this embodiment, the vacuum is replaced by a substantially non-compressible fluid which is moved from a reservoir (not shown) into and out of portions of support structure 730, e.g., holes 740, to move stamp material 720.

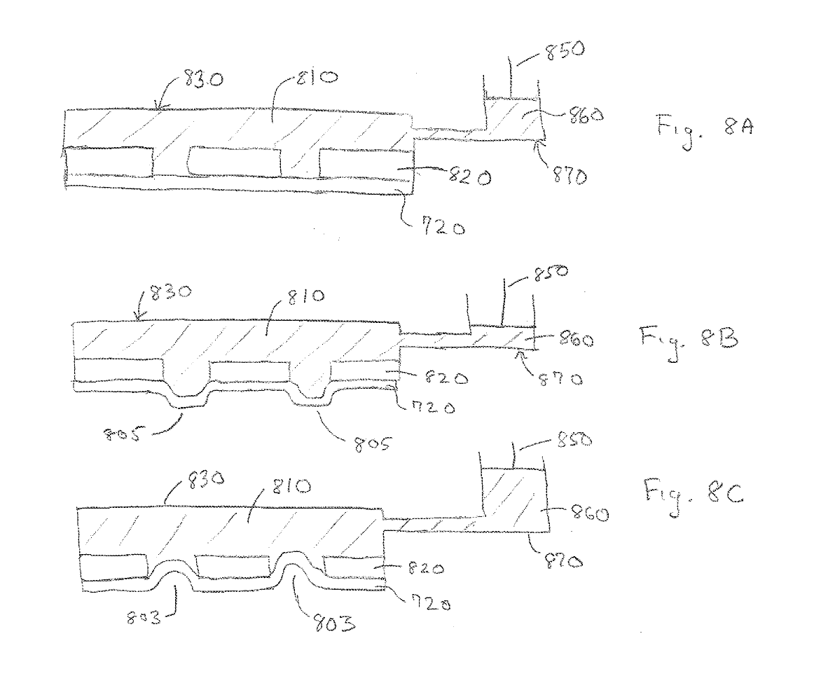

In yet another embodiment, the stamp is configured to bulge out beyond the original (or unactivated) surface of the stamp to selectively pick up dies 100. FIG. 8A shows a stamp 830 that includes solid regions 820 and a channel region 810. A fluid 860 is moved between a reservoir 870 and channel regions 810, for example using a piston 850. As fluid 860 is moved into channel regions 810, stamp material 720 bulges out and forms a multi-level surface that may be used to selectively attach to dies 100. FIG. 8B shows protruding regions 805 of stamp material 720. This approach may also be used to form recessed portions 803 of stamp material 720, as shown in FIG. 8C. This permits the same stamp 830 to pick up adjacent groups of dies 100 without requiring stamp 830 to move to different positions above the array of dies 100. While the structure shown in FIG. 8A-8C is configured to pick up two different groups of dies 100, the solid regions 820 and channel regions 810 may be configured to pick up any number of different groups of dies 100. Fluid 860 may include or consist essentially of, e.g., air or a liquid.

In yet another embodiment, stamp material may include or consist essentially of a material that may undergo a reversible change in adhesion properties, for example upon exposure to radiation, heat, moisture, or the like. The stamp may be configured to permit selective modification of the adhesion properties to permit pick up of selected dies or groups of dies. For example, stamp material 720 may include or consist essentially of a material that undergoes a reversible change in adhesion properties upon exposure to UV radiation. The stamp material may be selectively irradiated, for example through a mask, to cause some regions of the stamp material to have high tack in regions where it is desired to pick up a die and significantly lower tack in regions where it is desired not to pick up a die. In one embodiment, stamp material 720 is transparent to UV radiation and is exposed through the side opposite the dies 100.

Processes described herein may result in the formation of a coated die 500, as shown in FIG. 5, where all or a portion of substrate 110 has been removed from die 100. In some coated dies 500, die 100 may have a thickness in the range of about 1 μm to about 50 μm, or a range of about 2 μm to about 15 μm, and the thickness of wavelength-conversion material 400 may be in the range of about 10 μm to about 1000 μm, or in the range of about 50 μm to about 500 μm.

FIG. 5 shows a coated die 500 featuring one layer of wavelength-conversion material 400; however, this is not a limitation of the present invention, and in other embodiments wavelength-conversion material 400 comprises multiple layers, where one or more layers may include or consist essentially of a transparent binder or encapsulant and one or more may include or consist essentially of a wavelength-conversion material. FIG. 5 shows wavelength-conversion material 400 forming an essentially conformal layer around a portion of die 100; however, this is not a limitation of the present invention, and in other embodiments wavelength-conversion material 400 has other shapes.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A method of processing semiconductor devices, the method comprising:
forming a plurality of semiconductor layers on a substrate, at least some of the semiconductor layers collectively defining a light-emitting-diode (LED) structure;
forming a plurality of conductive contacts on a top surface of the semiconductor layers to define a plurality of LED dies disposed on the substrate, each of the LED dies comprising at least two of the conductive contacts on a first surface thereof;
bonding at least some of the LED dies to a temporary substrate, thereby forming a plurality of bonded LED dies each having at least two conductive contacts adjacent to the temporary substrate;
thereafter, removing the bonded LED dies from the substrate, the bonded LED dies remaining bonded to the temporary substrate;
applying a wavelength-conversion material over the bonded LED dies; and
removing the bonded LED dies from the temporary substrate.

2.-7. (canceled)

8. The method of claim 1, wherein the substrate comprises GaAs, GaP, silicon, or sapphire.

9. The method of claim 1, wherein at least one of the semiconductor layers comprises at least one of silicon, GaAs, InAs, AlAs, InP, GaP, AlP, InSb, GaSb, AlSb, GaN, InN, AlN, SiC, ZnO, or an alloy or mixture thereof.

10. The method of claim 1, wherein bonding at least some of the LED dies to the temporary substrate comprises bonding only some of the LED dies to the temporary substrate.

11. The method of claim 1, further comprising singulating the bonded LED dies by removing, from between the bonded LED dies, at least one of (i) a portion of at least one of the plurality of semiconductor layers or (ii) a portion of the wavelength-conversion material.

12. The method of claim 11, wherein the bonded dies are singulated after removing the bonded LED dies from the temporary substrate.

13. The method of claim 11, wherein singulating the bonded LED dies comprises cutting, sawing, dicing, laser cutting, water jet cutting, or die cutting.

14. The method of claim 11, wherein the bonded dies are singulated before removing the bonded LED dies from the temporary substrate.

15. The method of clam 11, further comprising transferring the bonded LED dies from the temporary substrate to a second temporary substrate prior to singulation.

16. The method of claim 1, wherein removing the bonded LED dies from the substrate comprises removing at least a portion of the substrate by at least one of laser lift-off, wet chemical etching, dry etching, sand blasting, lapping, or polishing.

17. The method of claim 1, wherein forming the plurality of semiconductor layers comprises epitaxial deposition.

18. The method of claim 1, further comprising, after forming the plurality of conductive contacts, removing a portion of at least one of the semiconductor layers, thereby at least partially separating the plurality of LED dies.

19. The method of claim 18, further comprising removing a portion of the substrate.

20. The method of claim 1, wherein the substrate comprises a semiconductor substrate.

21. The method of claim 1, wherein the wavelength-conversion material comprises one or more phosphors.

22. The method of claim 21, wherein the one or more phosphors each comprise a material selected from the group consisting of YAG:Ce, LuAG:Ce, aluminum garnet-based phosphor, nitride-based phosphor, oxynitride-based phosphor, silicate-based phosphor, and quantum dots.

23. The method of claim 1 wherein the wavelength-conversion material comprises a material selected from the group consisting of silicone, epoxy, glass, spin-on glass, polyimide, and polymers.

24.-25. (canceled)

26. The method of claim 1, wherein the wavelength-conversion material is applied over substantially all of each sidewall of each bonded LED die.

27. The method of claim 1, wherein each bonded LED die comprises electrical contacts only on the first surface thereof.

28. (canceled)

29. The method of claim 1, wherein applying the wavelength-conversion material comprises dispensing, casting, molding, or compression molding.

30. The method of claim 1, wherein the wavelength-conversion material comprises an encapsulant, and further comprising curing the encapsulant.

31. The method of claim 1, wherein a thickness of the wavelength-conversion material on the bonded LED dies is defined at least in part by a spacing between bonded LED dies on the temporary substrate.

32. The method of claim 1, further comprising electrically testing the bonded LED dies.

33.-45. (canceled)
